(19) United States
(12) Patent Application Publication
(10) Pub. No.: US 2006/0219861 A1
(43) Pub. Date: Oct. 5, 2006

(54) LOW-POWER SURVEILLANCE SENSOR

(75) Inventor: Roland A. Wood, Bloomington, MN (US)

Correspondence Address: HONEYWELL INTERNATIONAL INC., 101 COLUMBIA ROAD, P O BOX 2245, MORRISTOWN, NJ, 07962-2245, US

(73) Assignee: HONEYWELL INTERNATIONAL INC., Morristown, NJ (US)

(21) Appl. No.: 10/907,372

(22) Filed: Mar. 30, 2005

(51) Int. Cl. H01L 27/00

(52) U.S. Cl. 250/208.1

(57) ABSTRACT

A system and a method of operating imaging sensors in a lower power manner. In one illustrative embodiment, an image sensor system includes a sensor controller coupled to a sensor array. The sensor controller may have a higher power state that is active when reading the sensor array and a lower power state that is active between read operations. The sensor controller may read the sensor array at a reduced frame rate until movement or activity is detected in the scene, and then the sensor controller may read the sensor array at an increased frame rate for higher frame resolution. In some cases, less than all of the pixels in the sensor array may be read at some times to reduce power consumption, and more or all of the pixels may be read at other times to provide higher resolution.

### FIELD OF THE INVENTION

The present invention generally relates to image sensors, and more particularly to a low-power image sensor that may be used for surveillance and other applications.

### BACKGROUND OF THE INVENTION

Image sensors are used in a wide variety of applications. One application is perimeter and/or area surveillance. This application often requires image sensors to operate continuously to monitor the desired perimeter and/or area. In some cases, the positioning of the sensors is at locations without immediate access to a power supply making it desirable for the image sensor to be able to operate solely on battery power.

### SUMMARY OF THE INVENTION

The following summary of the invention is provided to facilitate an understanding of some of the innovative features unique to the present invention and is not intended to be a full description. A full appreciation of the invention can be gained by taking the entire specification, claims, drawings, and abstract as a whole.

The present invention provides for a system and a method of operating imaging sensors in a lower power manner. In one illustrative embodiment, an image sensor system includes a sensor controller coupled to a sensor array. The sensor controller may be adapted to read at least some of the sensor array pixels, and provide an output.

In some illustrative embodiments, at least a portion of the sensor controller has a higher power state, which is active when reading the at least part of the sensor array, and a lower power state, which is active between read operations. In one illustrative embodiment, the sensor controller may read at least some of the sensor array pixels at a reduced frame rate. A comparator may be provided for comparing at least some of the sensor array pixels of two or more pixel frames. A change detector may be coupled to the comparator for detecting a change between the two or more pixel frames.

When a change is detected by the change detector, the frame rate may be increased to capture more scene information. Thus, in some cases, the imaging sensor may be operated in a “trip wire” type mode, which may reduce operating power dramatically during periods of inactivity in the field of view, yet produce more detailed imagery relatively immediately when desired.

In some embodiments, the sensor array may also have a lower power and a higher power operating mode. The sensor array may be in the higher power operating mode during read operations, and in the lower power operating mode between successive read operations. This may also reduce the power consumption of the sensor. In some cases, such as when the sensor array is an infrared (IR) bolometer array, the sensor array may be continuously operated so that the sensor array remains thermally stable. However, this is not required in all embodiments.

In some cases, some read operations of the sensor array may read out every “nth” pixel of the sensor array, where “n” is an integer greater than one. For example, only a fraction of the pixels may be read out during periods of inactivity, and in some cases at a reduced frame rate. More pixels may be read out (e.g. every pixel), and in some cases at an increased frame rate, when a change is detected in the scene. This may also help reduce the power consumption of the image sensor.

### BRIEF DESCRIPTION OF THE DRAWINGS

FIG. 1 is a schematic diagram of an illustrative low-power sensing system;

FIG. 2 is a schematic diagram of an illustrative low-power sensing system including an infrared bolometer array;

FIG. 3 is a schematic diagram of an illustrative low-power sensing system including an infrared bolometer array;

FIG. 4 is a schematic diagram of an illustrative lower-power sensing system including an array of visible light sensors (e.g. Charge-Coupled Device or CCD);

FIG. 5 is a diagram of a process of operating a low-power sensing system;

FIG. 6 is a diagram of another process of operating a low-power sensing system; and

FIG. 7 is a diagram of an alternative process of operating a low-power sensing system.

### DETAILED DESCRIPTION OF THE DRAWINGS

The following description should be read with reference to the drawings wherein like reference numerals indicate like elements throughout the several views. The detailed description and drawings show several embodiments which are meant to be illustrative of the claimed invention.

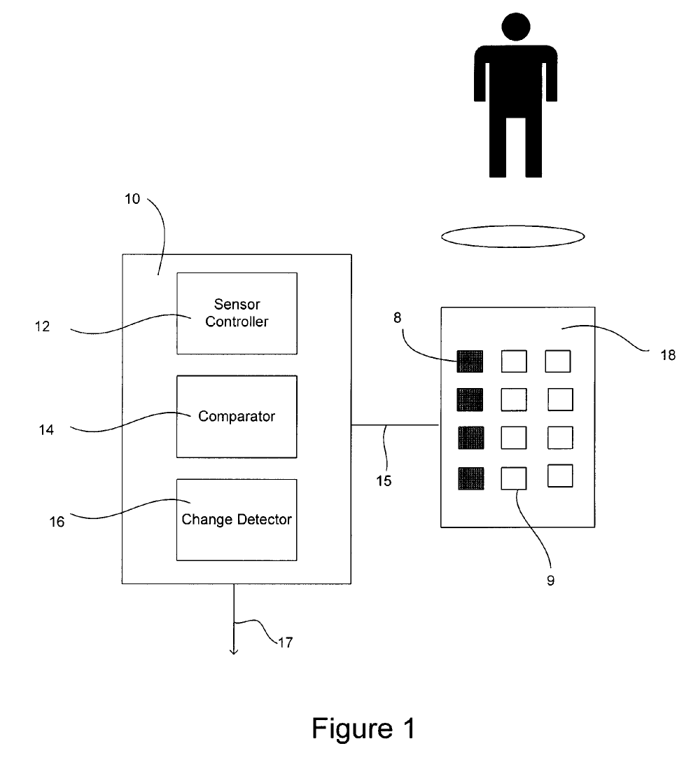

FIG. 1 is a schematic diagram of an illustrative sensing system. The illustrative sensing system includes a sensor array 18 and a controller 10. The illustrative controller 10 includes a sensor controller 12, a comparator 14, and a change detector 16. It is contemplated that the controller 10 may be implemented in software, hardware, or a combination thereof. In some cases, the controller 10 may activate a portion of the sensor array 8 while leaving the remaining sensors 9 inactive to reduce the power consumption of the sensor array 18. In other cases, the entire sensor array may be continuously active so that the sensor array remains thermally stable. This may be particularly useful when, for example, the sensor array is an infrared (IR) microbolometer sensor array. However, this is not required in all embodiments. The sensor array 18 may be, but is not limited to, an infrared (IR) bolometer array, a visible light sensor array (e.g. Charge-Coupled Device (CCD)), or any other suitable sensor array as desired.

In the illustrative embodiment, the sensor array 18 produces pixel frames at a selectable rate. In a typical real time application, a single frame may take 1/30th of a second, however, the time for one frame may be more or less. The sensor controller 12 is coupled to the sensor array 18 via an interface 15. The sensor controller 12 is adapted to read at least some of the sensor array 18 pixels and provide an output 17. In some embodiments, at least a portion of the sensor controller 12 has a higher power state, which is active when reading the sensor array 18, and a lower power state or “sleep” state between successive readings. The sensor controller 12 reads the sensor array 18 pixels and produces a pixel frame. The sensor controller 12 is in the lower power state for a time between reading successive pixel frames. For example, if the sensor array operates at a single frame per second, which may be 1/30 second, and the sensor controller 12 is in a sleep state between each reading, the power consumed is approximately 1/30 of a conventional image sensor operating at 30 frames per second. However, the embodiment is not limited to one frame per second, but may be any other number of frames per second whereby the power reduction would be adjusted accordingly.

Alternatively, or in addition, in some illustrative embodiments, every nth pixel of the sensor array 18 can be read out by the sensor controller 12, also reducing the power consumption of the sensor. By reducing the number of pixels read out by the sensor controller 12 to every nth pixel, the total number of pixels read may be reduced by n². Also, the time required to read the array is reduced by n², which when the sensor controller 12 is in a sleep state between successive reads of the sensor array, may reduce the power consumed by the sensor controller 12.

For example, if every 6th pixel is read, the number of pixels read out is reduced by a factor of 36, and the time required to read the sensor array 18 is 1/36 of the full array read time, thus reducing the power of the sensor controller 12 by a factor of about 36. In some cases, the use of a decreased frame rate and only reading every nth pixel may be used together or separate, as desired. If both are used, for example, one frame per second is read and every 6th pixel is read, the total power is reduced by about 1000 times relative to a conventional image sensor that reads every pixel at 30 frames per second.

In the illustrative embodiment, the comparator 14 may be used for comparing the sensor array pixels of two or more pixel frames. The change detector 16 may be coupled to the comparator 14, and may be used for detecting a change between the two or more pixel frames. For the change detector 16 to detect a change in the pixel frames, the change between the two or more pixel frames may exceed a certain threshold value. The threshold value may be any suitable threshold value, depending on the application. If the threshold value is exceeded, the frame rate of the sensor array 18 may be increased. In some cases, the increase is the maximum frame rate of the sensor array 18, but may be any desired frame rate. Also, all of the pixels may be read. Thus, the system can be low-power, but when needed, it can switch to a higher power state to more fully monitor the scene.

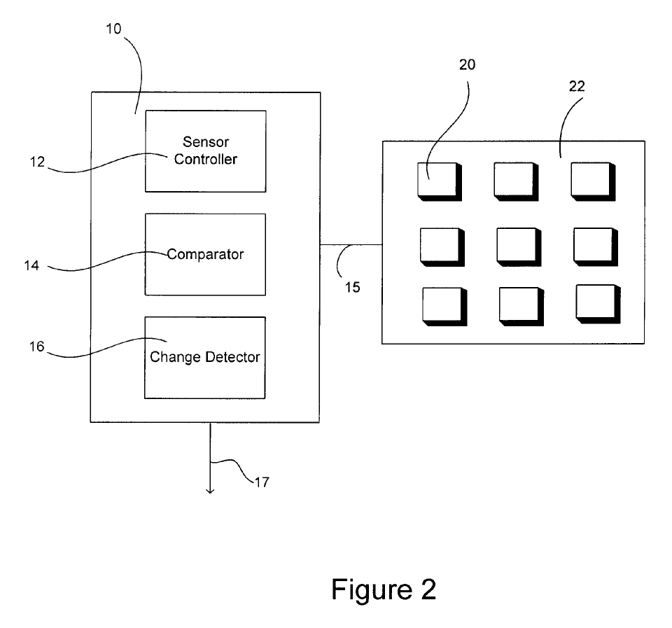

FIG. 2 is a schematic diagram of an illustrative lower-power sensing system including an array of sensors 20. Each sensor 20 may be sensitive to visible, infrared or some other wavelength of radiation, as desired. In one illustrative embodiment, each sensor 20 is an infrared sensor known as a bolometer. An infrared bolometer 20 is a thermal radiation detector that operates by absorbing incident infrared radiation, converting the absorbed energy into heat and then indicating the resulting temperature change by a change in electrical resistance or the like. In some cases, a read-out integrated circuit (ROIC) 22 may be provided to help read out the sensor values from the array of sensors. For example, ROIC 22 may sequentially measure a resistance of the individual bolometers 20 in the array in a relatively short time. As noted above, the bolometer array 20 may be coupled to the controller 10 via interface 15.

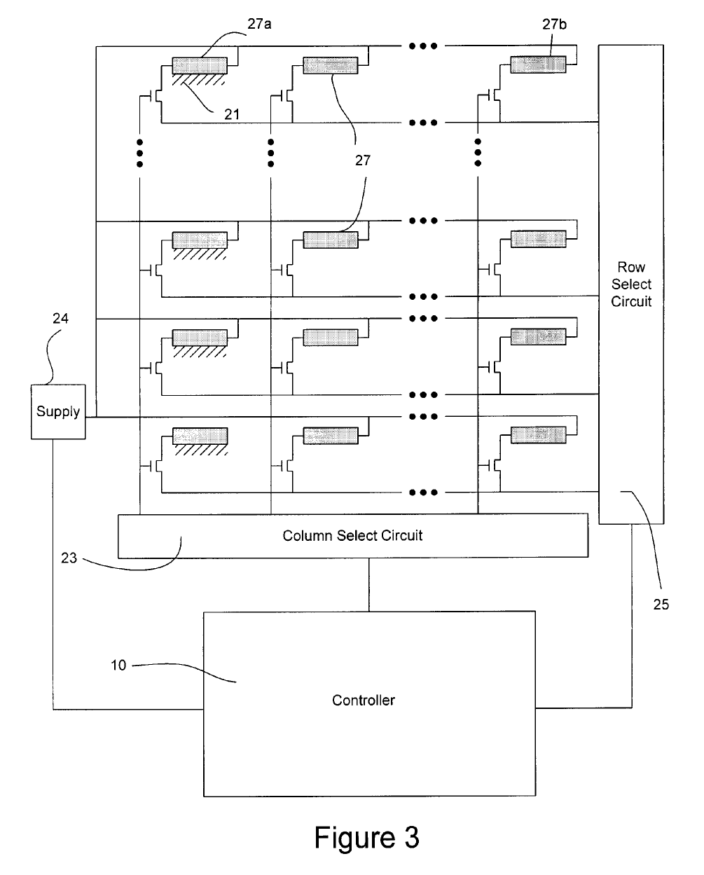

FIG. 3 is a schematic diagram of an illustrative lower-power bolometer array. In some cases, the bolometer array may include thin film resistors 27 with a relatively high temperature coefficient. One terminal of the thin film resistor 27 may be connected to a power supply voltage 24. The other terminal of the thin film resistor 27 may be connected to a corresponding row read line through a column select switch. In operation, the sensor elements 27 that are in a selected row are read in succession from a first sensor element 27a to a last sensor element 27b before the sensor elements 27 in the next row are read. To accomplish this, a row select circuit 25 selects a row and a column select circuit 23 sequentially activates each column. Once all the sensor elements 27 in a row are read, a next row is selected by the row select circuit 25. Then the column select circuit 23 again sequentially activates each column. This is continued until each row is read in the bolometer array 20. In another case, the sensor elements 27 may be activated so that each sensor element 27 in a diagonal is read. More generally, any arrangement of sensor elements 27 or readout sequence or method of activating sensor elements 27 may be used, as desired.

In some cases every nth sensor may be read. To accomplish this, and in one illustrative embodiment, the row select circuit 25 may select a row and the column select circuit 23 may sequentially active every nth sensor element 27 in the row. Once every nth sensor element 27 is read, the row select circuit 25 may select the next row. Then the column select circuit 23 again may sequentially activate every nth sensor element 27 in the row. This is continued until every row is read in the bolometer array 20.

Alternatively, the row select circuit 25 may select a row and the column select circuit 23 may sequentially activate every sensor element 27 in the row. Once every sensor element 27 is read, the row select circuit 25 may select the nth row. Then the column select circuit 23 again reads out every sensor element 27 in the row. Then the row select circuit 25 selects the next nth row. This is continued until every nth row is read in the bolometer array 20. These are just a few examples. It is contemplated, however, that every nth row may be read, every nth column may be read, or any other combination of activating the row and column sensor elements 27 may be used, as desired.

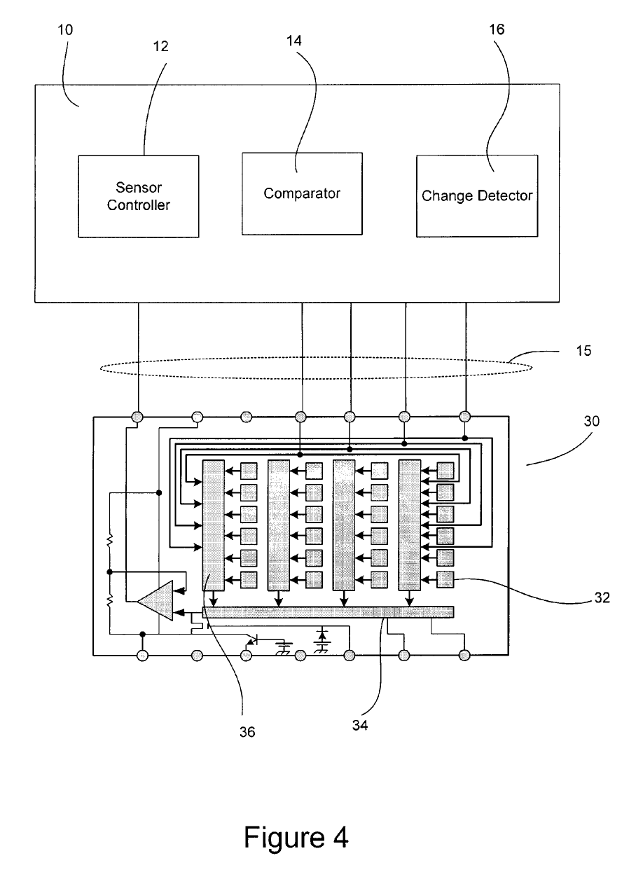

FIG. 4 is a schematic diagram of an illustrative lower-power visible sensing system including a Charge-Coupled Device (CCD). The CCD 30 includes an array of photo sensors 32. In many cases, the photo sensors 32 are connected to vertical registers 36, which are connected to a horizontal register 34. The output of the CCD 30 is sent to the controller 10 via interface 15.

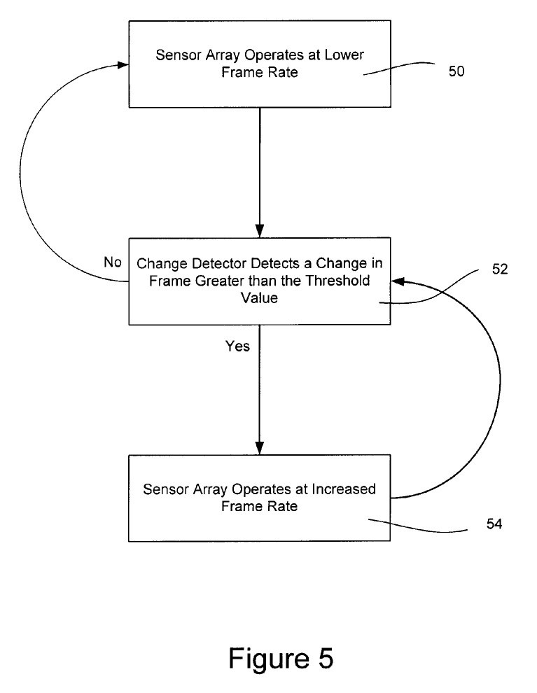

FIG. 5 is a flow diagram of an illustrative method of operating a sensing system. Initially, and as shown at block 50, the sensor array 18 may operate at a lower frame rate. In the illustrative embodiment, the sensor controller 12 has a higher power state and a lower power state. The sensor controller 12 operates in the higher power state when reading the sensor array 18. For example, the frame rate could be one frame per second. In some cases, a single frame may be 1/30th of a second. Thus, the sensor controller 12 may operate only 1/30th of the time relative to real time operation. As such, the power needed to operate the sensor controller 12 may be approximately 1/30 of the power needed to operate at real time rates.

After each frame is read by the sensor controller 12, the comparator 14 may compare the current frame to one or more previous frames. The change detector 16 then may detect a difference in the frames found by the comparator 14. If the change is not greater than a predetermined threshold value, then the sensor array 18 continues to operate at the lower frame rate. If the change detected is greater than the predetermined threshold value 52, the sensor array 18 may increase the frame rate 54. In some cases, the sensor array operates at the increased frame rate for a predetermined period of time, until the change detector does not detect a change greater than a threshold value, or for some other period of time, as desired. The sensor array may then return back to the lower frame rate, if desired.

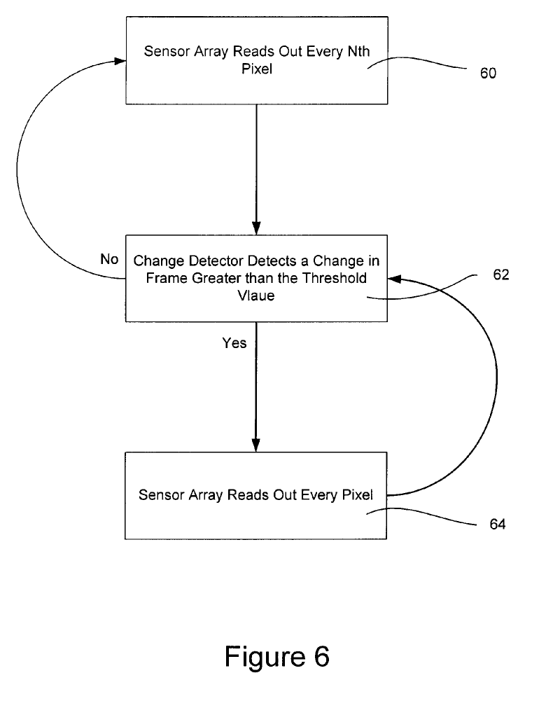

FIG. 6 is a flow diagram of another illustrative method of operating a sensing system. In this method, the sensor array 18 reads out only every nth pixel 60, where “n” is an integer greater than one. For example, if the sensor array reads out every 6th pixel, horizontally and vertically, the time needed for the sensor controller 12 to read the sensor array 18 is reduced by a factor of 36, and the power dissipated by the sensor controller 12 may be reduce to about 1/36th of the power dissipated when all pixels are read out. Similar to the previous method, a comparator 14 may compare successive frames of the sensor array 18, and the change detector 16 may detect a change in the pixel frames. If the change is not greater than a predetermined threshold value, the sensor array 18 may continue to read out every nth pixel for each frame. If the change is greater than the predetermined threshold value 62, the sensor array 18 may read out more pixels 64, such as every pixel, to increase the resolution of the image produced by the sensor system. The sensor array 18 may continue to read out every pixel for a predetermined time period, until the change detector 16 detects a change not greater than a predetermined threshold value, or some other time as desired. Then the sensor array 18 may return to read out every nth pixel. The method of FIG. 6 may be used in conjunction with the method described with reference to FIG. 5, if desired.

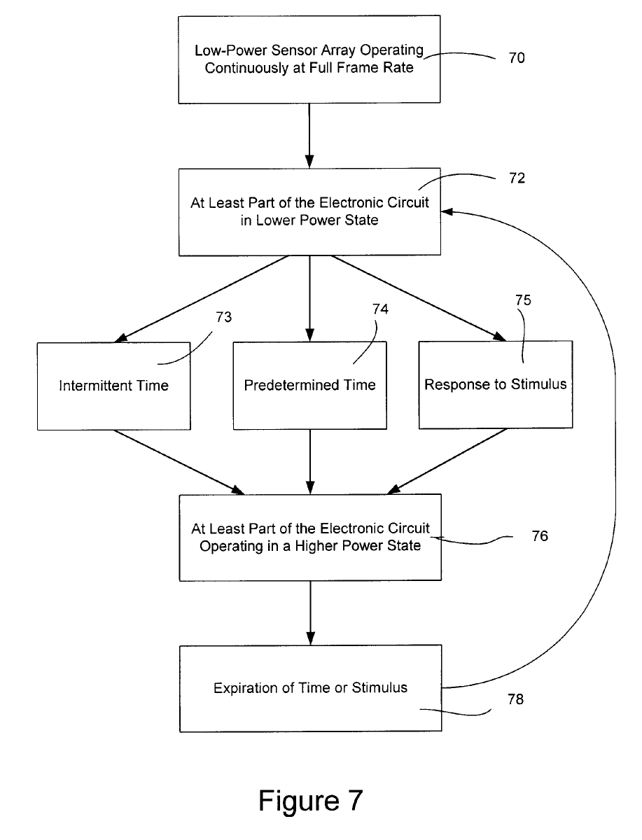

FIG. 7 is a flow diagram of another illustrative method of operating a sensing system. In this illustrative method, a lower-power sensor array 18 is used. In some cases, the sensor array 18 is an infrared bolometer array 20 using a low-power ROIC 22 design. The sensor array 18 is operated continuously at the full frame rate 70, so the sensor array 18 has a constant power state and is thus thermally stable. This can be important in infrared bolometer applications, since IR bolomoters are measuring relatively small heat signatures.

Also, at least part of the controller 10 may be in a lower power state 72. In the illustrative embodiment, the controller 10 is operated intermittently 73, at predetermined times 74, in response to a stimulus 75, or by any other means as desired. When the controller 10 is operated, it operates in a higher power state 76. At the expiration of the time or stimulus 78, the controller 10 returns to the lower power state 72. For example, the controller 10 may operate only three times per second to accept three pixel frames from the sensor array 18, and is in a lower power state between readings. Thus, the power dissipated by the image sensor may be reduced.

Having thus described the preferred embodiments of the present invention, those of skill in the art will readily appreciate that yet other embodiments may be made and used within the scope of the claims hereto attached. Numerous advantages of the invention covered by this document have been set forth in the foregoing description. It will be understood, however, that this disclosure is, in many respect, only illustrative. Changes may be made in details, particularly in matters of shape, size, and arrangement of parts without exceeding the scope of the invention. The invention's scope is, of course, defined in the language in which the appended claims are expressed.

1. A system comprising:
a sensor array having a number of pixels; and
a sensor controller coupled to the sensor array, the sensor controller adapted to read at least some of the sensor array pixels and provide an output, at least a portion of the sensor controller having a higher power state that is active when reading the at least part of the sensor array and a lower power state.

2. The system of claim 1, wherein the sensor controller is adapted to read the at least some of the sensor array pixels to produce a pixel frame.

3. The system of claim 2, wherein the sensor controller is in the lower power state for a time between reading successive pixel frames.

4. The system of claim 3, wherein the sensor controller is adapted to read two or more pixel frames at a frame rate.

5. The system of claim 4, wherein the frame rate is selectable.

6. The system of claim 5 further comprising:
a comparator for comparing the at least some of the sensor array pixels of two or more pixel frames; and
a change detector coupled to the comparator for detecting a change between the two or more pixel frames.

7. The system of claim 6, wherein the change is only detected when the difference between the two or more pixel frames exceeds a threshold value.

8. The system of claim 6, wherein the frame rate is increased when a change is detected by the change detector.

9. The system of claim 6, wherein more of the sensor array pixels are read when an event occurs.

10. The system of claim 9, wherein the event is a change detected by the change detector.

11. The system of claim 9, wherein the event is a passage of time.

12. The system of claim 9, wherein the event is a response to a stimulus.

13. The system of claim 1, wherein the at least part of the sensor array that is read includes every nth pixel of the sensor array, where “n” is an integer greater than one.

14. The system of claim 1, wherein the sensor array does not have a lower power state.

15. The system of claim 1, wherein the sensor controller reads the at least part of the sensor array in response to a stimulus.

16. The system of claim 1, wherein the sensor array is an infrared sensor array.

17. The system of claim 1, wherein the sensor array is a visible sensor array.

18. The system of claim 1, wherein the sensor array is a Charge-Coupled-Device (CCD).

19. A system comprising:
a sensor array having a number of pixels; and
a sensor controller coupled to the sensor array, the sensor controller adapted to read at least some of the sensor array pixels and provide an output, wherein more of the pixels are read when an event is detected.

20. The system of claim 19 further comprising:
a comparator for comparing the at least some of the sensor array pixels of two or more pixel frames; and
a change detector coupled to the comparator for detecting a change between the two or more pixel frames.

21. The system of claim 20, wherein the event is a change detected by the change detector.

22. The system of claim 19, wherein the event is a passage of time.

23. The system of claim 19, wherein the event is a response to a stimulus.

24. A method for operating a sensor array having a number of sensor array pixels and a sensor controller, wherein the sensor controller is adapted to read at least some of the sensor array pixels and provide an output, the method comprising:
placing the sensor controller in a higher power state;
reading at least some of the sensor array pixels; and
placing the sensor controller in a lower power state.

25. The method of claim 24, wherein the sensor controller is adapted to read the at least some of the sensor array pixels to produce a pixel frame.

26. The method of claim 25, wherein the sensor controller is in the lower power state for a time between reading successive pixel frames.

27. The method of claim 26, wherein the sensor controller is adapted to read two or more pixel frames at a frame rate.

28. The method of claim 27, wherein the frame rate is selectable.

29. The method of claim 28 further comprising:
comparator for comparing the at least some of the sensor array pixels of two or more pixel frames; and
change detector coupled to the comparator for detecting a change between the two or more pixel frames.

30. The method of claim 29, wherein the change is only detected when the difference between the two or more pixel frames exceeds a threshold value.

31. The method of claim 29, wherein the frame rate is increased when a change is detected by the change detector.

32. The method of claim 24, wherein the at least part of the sensor array that is read includes every nth pixel of the sensor array, where “n” is an integer greater than one.

33. The method of claim 24, wherein the sensor array does not have a lower power state.

34. The method of claim 24, wherein the sensor controller reads the at least part of the sensor array in response to a stimulus.

35. The method of claim 24, wherein the sensor array is an infrared sensor array.

36. The method of claim 24, wherein the sensor array is a visible sensor array.

37. The method of claim 24, wherein the sensor array is a Charge-Coupled-Device (CCD).

38. A method for operating a sensor array having a number of sensor array pixels and a sensor controller, wherein the sensor controller is adapted to read at least some of the sensor array pixels and provide an output, the method comprising:
reading at least some of the sensor array pixels; and
increasing the number of sensor array pixels read, wherein the number of sensor array pixels read increases when an event occurs.

39. The method of claim 38 further comprising:
a comparator for comparing the at least some of the sensor array pixels of two or more pixel frames; and
a change detector coupled to the comparator for detecting a change between the two or more pixel frames.

40. The method of claim 39, wherein the event is a change detected by the change detector.

41. The method of claim 38, wherein the event is a passage of time.

42. The method of claim 38, wherein the event is a response to a stimulus.

43. A method for operating a sensor array having a number of sensor array pixels and a sensor controller, wherein the sensor controller is adapted to read at least some of the sensor array pixels and provide an output, the method comprising:
placing the sensor controller in a higher power state;
reading at least some of the sensor array pixels;
placing the sensor controller in a lower power state; and
increasing the number of sensor array pixels read,
wherein the number of sensor array pixels read increases and the sensor controller is in a higher power state when an event occurs.

44. The method of claim 43, wherein the event is a change detected in the scene.

45. The method of claim 43, wherein the event is a passage of time.

46. The method of claim 43, wherein the event is a response to a stimulus.
